(19) United States
(12) Patent Application Publication
(10) Pub. No.: US 2011/0050209 A1
(43) Pub. Date: Mar. 3, 2011

(54) METHOD AND APPARATUS FOR UNAMBIGUOUS DETERMINATION OF THE ROTOR POSITION OF AN ELECTRICAL MACHINE

(76) Inventor: Rainer Nase, Sulzbach (DE)

(21) Appl. No.: 12/682,315

(22) PCT Filed: Oct. 3, 2008
(86) PCT No.: PCT/EP2008/063282

§ 371 Date: Jun. 28, 2010

(30) Foreign Application Priority Data
Oct. 9, 2007 (CH) 1566/07

(51) Int. Cl. G01R 19/14

(52) U.S. Cl. 324/133

(57) ABSTRACT

The method for operating an electrical machine (32) having three phases (A, B, C) and a connection associated with each of the phases (A, B, C) for determining the rotor position (φ), including the rotor polarity at a standstill, comprising, for at least two of the phases:
a) applying a pulsed voltage (Up) between the two connections associated with the other two phases;
b) measuring the voltage thus induced at the connection associated with the phase;
c) analyzing the variation of the referenced induced voltage over time; and
d) determining the rotor polarity on the basis of the referenced analyses.

A measure of the deviation of the variation of the induced voltage over time compared to the variation of the pulsed voltage (Up) over time is advantageously determined in step c).

Rotor position (φ) is determined in a quick, accurate, cost-saving, and space-saving manner.

### RELATED APPLICATION

This application is a U.S. national phase application under 35 U.S.C. §371 of International Application No. PCT/EP2008/063282 filed Oct. 3, 2008 with claiming priority of Switzerland Patent Application No. 1566/07 filed Oct. 9, 2007.

### TECHNICAL FIELD OF THE INVENTION

The invention relates to the field of electrical engineering, more precisely, to electrical machines, i.e., electric motors and generators. The invention relates to an appliance for determining a rotor position including the rotor polarity at a standstill, of an electrical maching having three phases and a connection associated with each of the phases, and a method for operating the electrical machine for determining rotor position including the rotor polarity at a standstill, for at least two of the phases.

### BACKGROUND INFORMATION

For controlled commutated electrical machines it is problematic that, as a rule, such machines are initially in an unknown starting position (angular position of the rotor). For optimal start-up of the electrical machine it would be desirable to know the exact starting position. This problem may be solved using appropriate position sensors, but this is complicated and expensive. Therefore, a sensorless operation is desirable, at least in the sense that no elements are required which are not already anyway needed for normal operation of the electrical machine.

It is known from the prior art to operate the electrical machine, without knowledge of the starting position, in a suboptimal manner during an alignment phase and a subsequent blind commutation, until the electrical machine has reached rotational speeds which allow the position to be easily determined.

The use of high voltages to force the rotor into a defined starting position has also been proposed.

From DE 10 2006 043 683 A1 a method is known for operating an electric motor during its run-up phase, in which current pulses are measured and evaluated.

A device is known from DE 10 2006 046 637 A1 for obtaining information about the operating state of electrical machines, in which a potential at the star point is determined. In addition, use is made of a change in inductance of pole winding phase conductors as a result of current flow through the phase conductors.

### SUMMARY OF THE INVENTION

An object of the invention is to provide an appliance and a method which allow to unambiguously determine the rotor position of an electrical machine.

A further object of the invention is to realize this in a simple manner.

A further object of the invention is to realize this using elements which are present anyway for operating the electrical machine.

A further object of the invention is to allow to unambiguously determine the rotor position of an electrical machine within a short period of time.

At least one of these objects is achieved using applicances and methods in accordance with the invention as disclosed herein.

The method for operating an electrical machine having three phases and a connection associated with each of the phases is characterized in that for determining the rotor position including the rotor polarity at a standstill, for at least two of the phases the following steps are carried out:
a) applying a pulsed voltage between the two connections associated with the other two phases;
b) measuring the voltage thus induced at the connection associated with the phase;
c) analyzing the variation over time of said induced voltage;
   and carrying out the following step:
d) determining the rotor polarity on the basis of said analyses.

It turned out that by using the referenced analysis, the ambiguity which exists in the prior art in determining the rotor position may be eliminated, and the rotor position may be unambiguously determined, even without exerting appreciable forces on the electrical machine.

Using the term “electrical machine” we refer to the term “electrical machine” as used in the field of electrical engineering, i.e. we mean electro-mechanical converters (electric motors) and mechanical-electrical converters (generators).

An electrical machine has a stator and a rotor which are rotatable relative to one another. The stator generates a variable magnetic field without having to undergo motion, and for this purpose has coils which embody the phases. The rotor generates a magnetic field having an orientation which is rigidly coupled to its mechanical/physical orientation.

The referenced connections are connections of the coils of the stator. The coils may be interconnected in a star-shaped or as well in a triangular configuration. It is known from the teaching that the topology of the star-shaped connection may be converted to the topology of the triangular connection by transformation of the mathematical equations describing the topology. A phase and the corresponding coil, respectively, may be associated with each of the three connections, regardless of the wiring.

It is noted that, assuming a star-shaped connection, no measurements are necessary at the star point to allow the rotor position to be unequivocally determined; likewise, applying a potential to the star point for this purpose is not necessary. The method is therefore less complicated.

The term “standstill” refers to a standstill of the rotor relative to the stator, which at least in practical terms may be regarded as a standstill.

In one embodiment the electrical machine is a controlled commutated machine.

In one embodiment the electrical machine is a block-commutated electrical machine.

In one embodiment the electrical machine is a sinus-commutated electrical machine. The sinus commutation may be accomplished by means of pulse width modulation (PWM) or in some other manner.

In one embodiment the electrical machine is a synchronous machine.

In one embodiment the electrical machine is a permanent-field machine.

In one embodiment the electrical machine is a dynamically excited machine.

In one embodiment, in step c) a measure of the deviation of the variation over time of the induced voltage compared to the variation over time of the pulsed voltage is determined, in particular a measure of the deviation of the slopes of the induced voltage with respect to the pulsed voltage.

In one embodiment said measure is a variable which is proportional to the deviation.

In one embodiment the measure is determined by carrying out at least one averaging operation.

In one embodiment the measure is determined by carrying out at least one approximation operation.

In one embodiment the measure is determined in a point-wise way.

In one embodiment the measure is a measure of the quotient of the induced voltage and the pulsed voltage.

In one embodiment, the pulsed voltage has at least a portion showing a substantially constant voltage, and in step c) a measure of the slope of the induced voltage is determined during the at least one portion showing the substantially constant voltage.

In one embodiment the voltage-time integral of the pulsed voltage substantially vanishes.

In one embodiment the pulsed voltage undergoes a change in polarity (reversal of voltage sign) at least once.

In one embodiment the pulsed voltage is periodic, and the voltage-time integral is substantially zero over each period.

This allows the currents flowing due to the applied pulsed voltage to be kept small.

In one embodiment the pulsed voltage is a rectangular or pulse width modulation signal.

Such pulsed voltages are easily generated, and in particular may often be generated using means which are anyway present for operating the electrical machine.

In one embodiment the pulsed voltage is a symmetrical rectangle (pulse width ratio 50%/50%).

In one embodiment the rectangular or pulse width modulation signal starts with a first state during a first time segment, followed by a second state, different from the first state, during a second time segment, the time integral of the pulsed voltage over the first and second time segments being substantially opposite and equal to the time integral of the pulsed voltage over the first time segment. Thus, the time integral of the pulsed voltage over the second time segment has essentially twice the negative value of the time integral of the pulsed voltage over the first time segment.

The two states of a rectangular or pulse width modulation signal are also referred to as a pulse and pause; i.e. they are characterized by maximum voltage and minimum voltage, respectively. The voltage changes between two successive states; in particular the polarity sign typically changes.

In one embodiment the voltage-time integral over the entire duration of the pulsed voltage vanishes. It is thus possible to achieve that the time integral of the current flowing due to the pulsed voltage is substantially zero.

In one embodiment the pulsed voltage ends with a third state during a third time segment, the time integral of the pulsed voltage over the third time segment being essentially equal to, or essentially opposite and equal to the time integral of the pulsed voltage over the first time segment.

In one embodiment the second state is followed by N further states (N≧1), each having a voltage-time integral which is substantially opposite and equal to the voltage-time integral over the respective time segment of the respective preceding state.

In one embodiment the pulsed voltage is applied symmetrically between the two connections, and the pulsed voltage is a rectangular or pulse width modulation signal which starts with a first state of a first time period, followed by a second state, different from the first state, of a second time period, the second time period being twice as long as the first time period. As a result of the longer time period it is possible to obtain more accurate measured values for the induced voltage which are less distorted by noise. It is also possible to compare a value (an average value, for example) from the first half of the second time period to a corresponding value from the second half of the second time period.

In one embodiment using the referenced symmetrical wiring of the connections, the pulse width modulation signal ends with a state of the first time period following a state, different from that state, of a second time period, the second time period being twice as long as the first time period.

The end state is the first state, or the end state is the second state (and the state preceding is the corresponding other state).

In one embodiment, for determining the rotor position including the rotor polarity at a standstill, for the at least two phases the following step is carried out:
e) determining a voltage difference from said induced voltage;
   and the following step is carried out:
f) determining the rotor position (q) based on said voltage differences.

It is noted that without carrying out step d), the rotor position would not be unambiguously determined, but be determined with ambiguity.

It is noted that the possible designs of the pulsed voltage described above may also be used without determining the rotor polarity, i.e., for example, for an ambiguous determination of the rotor position using the referenced voltage differences. A corresponding method for determining the rotor position at a standstill for an electrical machine having three phases (A, B, C) and a connection associated with each of the phases (A, B, C) is characterized by carrying out steps a), b), and e) for at least two of the phases, and by carrying out step f), the pulsed voltage being one of those described above. This allows the time integral of the current flowing due to the applied pulsed voltage to be kept small.

In one embodiment, step f) comprises a comparison to pre-defined values for the voltage differences.

In one embodiment, step d) comprises a comparison to specified values.

In one embodiment, such specified values are obtained from a model.

In one embodiment, such specified values are obtained from prior measurements.

In one embodiment the steps are carried out for all three phases. This increases the accuracy, and due to redundancy allows a check which gives more accurate and reliable results.

The applicance for determining a rotor position including the rotor polarity at a standstill, of an electrical machine having three phases and a connection associated with each of the phases includes:
a voltage source for generating a pulsed voltage;
a voltage measuring device for measuring electrical voltages;
a wiring system for wiring the three connections selectably with the voltage source or the voltage measuring device.

The applicance is designed in such a way that to at least two different pairs of the connections the pulsed voltage is successively applicable and an induced voltage thus occurring at the respective third connection is measurable using the voltage measuring device. The device furthermore includes:
an analysis unit for analyzing the variation over time of the induced voltages measured using the voltage measuring device; and
an evaluation unit for determining the rotor polarity based on at least two of said analyses.

The voltage source is understood to mean a power source which is able to supply an electrical voltage.

In one embodiment the voltage source is a direct voltage source, i.e. a power source which is able to supply an essentially constant electrical voltage, for example a battery.

In one embodiment the voltage source is the voltage source which is provided also for normal operation of the electrical machine. The device may thus be particularly small, and may be manufactured particularly easily and economically.

In one embodiment the analysis unit is provided for determining a measure of the deviation of the variation over time of the induced voltage with respect to the variation over time of the pulsed voltage.

In one embodiment the analysis unit is provided also for determining a voltage difference from said induced voltage, and the evaluation unit is provided also for determining the rotor position based on the referenced voltage differences.

The analysis unit and/or the evaluation unit may be divided into separate, operationally interconnected units, or may be completely or partially combined into a single unit. The same applies for the other functional components described above or below.

In one embodiment the appliance has a memory unit for storing comparative values for the referenced voltage differences, and/or comparative values for analysis results of said variations over time of said induced voltages.

The invention comprises appliances having features which correspond to the features of the described methods, and vice versa.

The arrangement according to the invention comprises an electrical machine having three phases, and a connection associated with each of the phases, and is characterized in that it comprises an applicance according to the invention.

It is noted that the above-described embodiments may each be combined with one or more of the other described embodiments.

Further embodiments and advantages result from the dependent claims and the figures.

### BRIEF DESCRIPTION OF THE DRAWINGS

The subject matter of the invention is explained below in greater detail with reference to exemplary embodiments and the accompanying drawings, which schematically show:

FIG. 1 a simplified block diagram of an arrangement according to the invention;

FIG. 2 a sketch for illustrating a permanent-field synchronous machine;

FIG. 3 a simplified block diagram of the wiring for a phase pair;

FIG. 4 a voltage-time diagram of a pulsed voltage;

FIG. 5 a voltage-time diagram of voltages induced by the pulsed voltage of FIG. 4;

FIG. 6 a current-time diagram of the currents flowing due to the pulsed voltage of FIG. 4;

FIG. 7 a voltage-time diagram of a pulsed voltage and the corresponding current-time diagram;

FIG. 8 a voltage-time diagram of the voltage induced by the pulsed voltage of FIG. 7;

FIG. 9 a voltage-time diagram of the voltage induced by the pulsed voltage of FIG. 7;

FIG. 10 a voltage-time diagram of an asymmetrically applied pulsed voltage;

FIG. 11 a current-time diagram of the current flowing due to the pulsed voltage of FIG. 10; and

FIG. 12 a diagram of curves as a function of the rotor position.

The reference symbols used in the drawings and their meanings are summarized in the list of reference symbols. Parts not essential for understanding the invention are sometimes not illustrated. The described embodiments are examples of the subject matter of the invention and have no limiting effect.

### WAYS FOR CARRYING OUT THE INVENTION

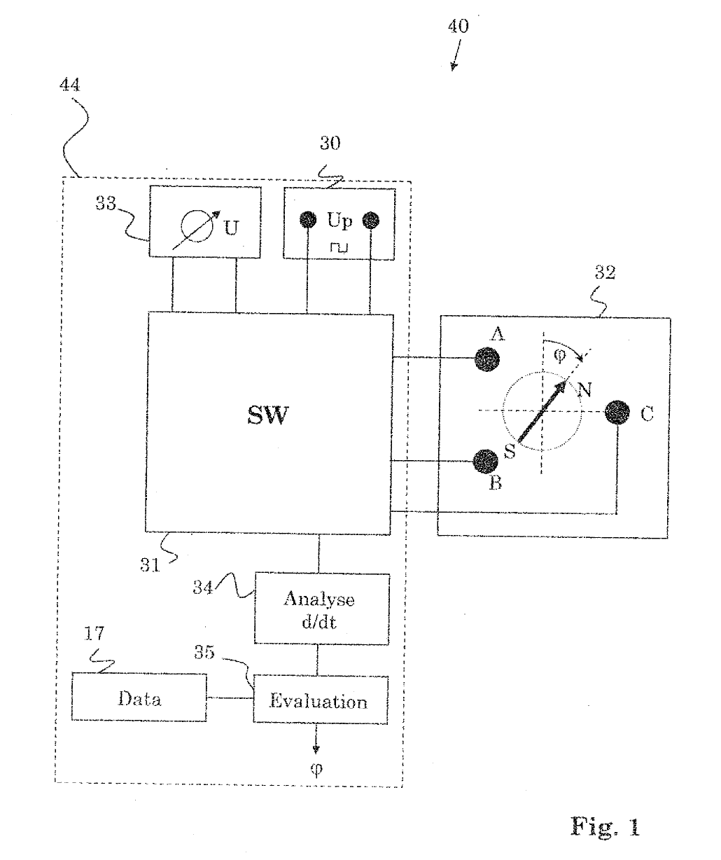

FIG. 1 shows a simplified schematic block diagram of an arrangement 40 according to the invention. This arrangement comprises an electrical machine 32, for example a brushless direct current (BLDC) machine, and an appliance 44 according to the invention. The electrical machine 32 is a three-phase machine having phases A, B, C, each embodied as a coil. The rotor of the machine 32 is symbolically shown in FIG. 1 as an arrow having a north and a south pole (N; S), and has an orientation, denoted by the angle φ, which is also referred to as the rotor position. The angle φ may assume values from 0° to 360°. Using known methods, the determination of φ is not unequivocal, but φ may only be determined with ambiguity; i.e., the rotor polarity, which allows an unequivocal association of the north and south poles, is not known. The rotor polarity may be determined using the described appliance and the method further described below.

The appliance 44 includes a voltage source 30, for example a direct voltage source such as a battery, a wiring system 31, a voltage measuring device 33, for example a voltmeter, an analysis unit 34, an evaluation unit 35, and a memory unit 17.

By means of the appliance 44, it is possible not only to determine the rotor position φ at standstill, but also to run up the machine 32 and to operate the machine 32 in the normal operating modes, i.e., to control the commutation.

The principle of operation of the appliance 44 and of the arrangement 40 will become clear from the following description.

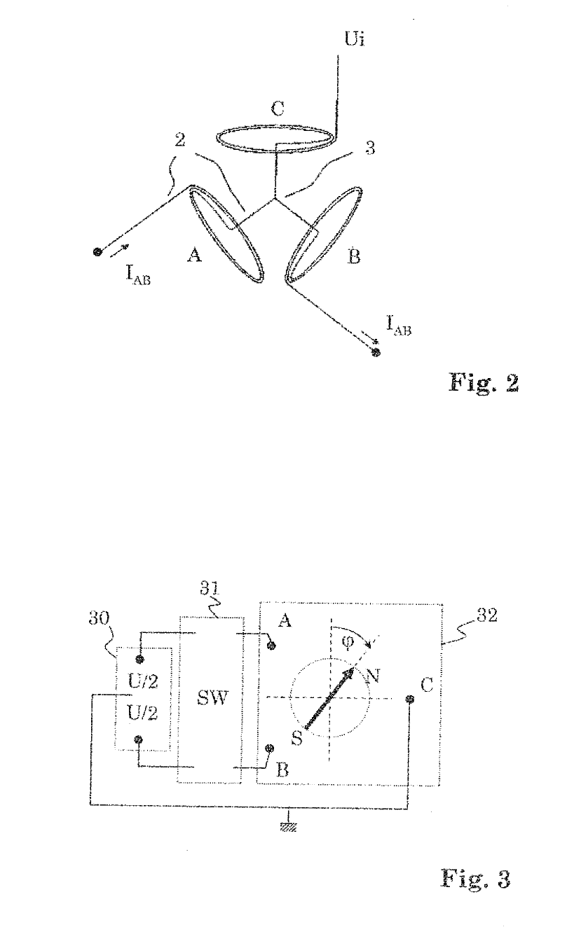

FIG. 2 shows a schematic sketch for illustrating a permanent-field synchronous machine. The three phases and their coils, respectively, are identified by reference symbols A, B, C. Each phase has two inputs/outputs 2 (indicated for phase A). In the star-shaped interconnection of the phases illustrated in FIG. 2, one input/output 2 for each phase is combined into a star point 3, and the other three connections are externally conducted and to them voltages may be applied for commutation. When in a machine according to FIG. 2 a voltage (referred to below as U_{AB}) is applied between the points illustrated as dark circles, the indicated current I_{AB} flows. The permanent magnets of the illustrated synchronous machine are not shown in FIG. 2.

This causes a voltage Ui (referred to as U_{C} below) to be induced in phase C. When the applied voltage U_{AB} is suitably selected and appropriately evaluated, information may be obtained from Ui concerning the rotor position, including the rotor polarity. For this purpose, however, at least two different pairs of phases must successively be appropriately wired and the induced voltage Ui at the particular remaining (free) third connection must be measured and evaluated. For dynamically excited machines, when the measurements are carried out a voltage must generally be applied in order to generate a defined magnetic field, whereas otherwise, no defined rotor position exists.

FIG. 3 shows a simplified block diagram of the wiring of a phase pair, namely, A, B. In FIG. 3 the voltage source 30 is symmetrically connected.

The wiring system 31 is used to establish the respective necessary connections between phases A, B, C, and their respective connections, respectively, on the one hand and between the voltage source 30 and the voltage measuring device 33 on the other hand.

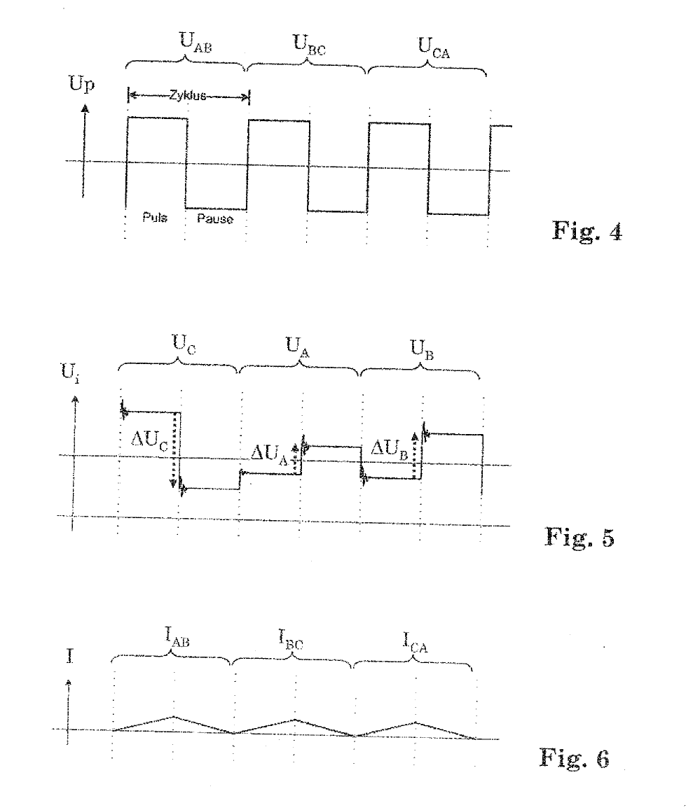

FIG. 4 shows a voltage-time diagram of a pulsed voltage Up. In the first cycle Up is applied to phases A and B, and is therefore designated as U_{AB}; in the second cycle Up is applied to phases B and C and is therefore designated as U_{BC}; and in the third cycle Up is applied to phases C and A and is therefore designated as U_{CA}. The illustrated voltage Up is a rectangular signal; as is customary for rectangular and pulse width modulation (PWM) signals, the time segment of maximum voltage is designated as “Pulse,” and the time segment of minimum voltage (zero or, as in FIG. 4, negative) is designated as “Pause.” One cycle is composed of a pulse and a pause following successively.

FIG. 5 schematically shows a voltage-time diagram of voltages Ui induced by the pulsed voltage Up from FIG. 4; the induced voltages are measured using the voltage measuring device 33 at the respective free connection, and are correspondingly designated as U_{C}, U_{A}, U_{B}.

Each pole reversal (change between pulse and pause) results in voltage fluctuations, which are symbolically illustrated in FIG. 5.

A determination of the voltage differences ΔU_{A}, ΔU_{B}, ΔU_{C} allows the rotor position φ to be determined except for the rotor polarity, for example by comparison with data like those illustrated in FIG. 12.

FIG. 12 shows in an exemplary way somewhat schematized curves for voltage differences ΔU_{A}, ΔU_{B}, ΔU_{C} as a function of the rotor position cp. It can be seen that the curves for ΔU_{A}, ΔU_{B}, and ΔU_{C} repeat after 180°, so that the rotor polarity remains unknown. The curves illustrated in FIG. 12 may be obtained by appropriate measurements of the electrical machine, or also by modeling. It is also apparent from FIG. 12 that for determining the rotor position φ except for the rotor polarity, two of the three voltage differences are in fact sufficient. However, measuring all three gives more accurate and reliable results (redundancy); the sum over all three voltage differences ΔU_{A}, ΔU_{B}, ΔU_{C} is zero.

FIG. 6 shows a schematized current-time diagram of currents I_{AB}, I_{BC}, I_{CA} flowing due to the pulsed voltage of FIG. 4. After each cycle the current is again zero. However, the time integral over the current increases with time. Thus, there is a non-vanishing average current which results in a directed force effect which advantageously should be avoided.

FIG. 7 shows a voltage-time diagram of a pulsed voltage U_{AB} which is applied to the connections of phases A and B, and the corresponding current-time diagram for I_{AB}. Due to symmetry, the characteristics for a different wiring scheme are completely analogous. By selecting this particular curve shape in which the polarity is reversed after each cycle, the current-time integral may be kept small and even periodically vanishes after two cycles (see the points in time identified by the outlined arrows). The cycle known from FIG. 4 is maintained as the “cycle.” At the points in time identified by the outlined arrows it is particularly advantageous to have the pulsed voltage Up end; of course, the signal may also be lengthened, advantageously by a multiple of two cycles.

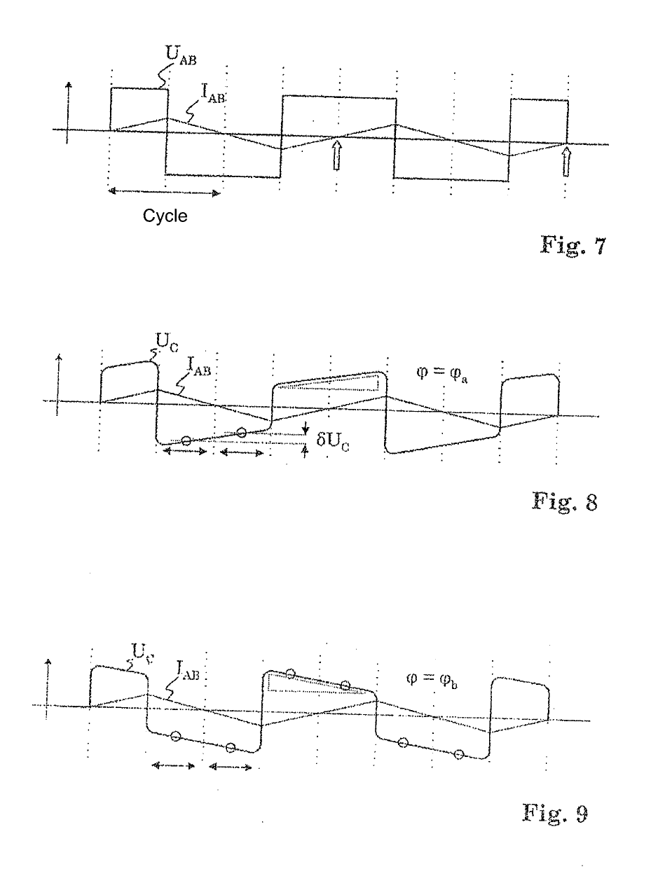

FIG. 8 schematically shows a voltage-time diagram of the voltage U_{C} induced by the pulsed voltage from FIG. 7, and once again the current-time diagram illustrated in FIG. 7.

FIG. 8 shows in a highly exaggerated manner a very important characteristic of the induced voltage U_{C} which is not discernible from FIG. 5: U_{C} changes during the time periods of constant voltage of U_{AB}. In particular, U_{C} has a different slope than the pulsed voltage U_{AB}.

FIG. 9 shows in a similar fashion as FIG. 8 a voltage-time diagram of the voltage induced by the pulsed voltage of FIG. 7, but for a different rotor position φb≠φa. In the case illustrated, the expression φa=φb+180° is approximately valid. In the case illustrated in FIG. 9, the slope of the induced voltage U_{C} is once again different from that in FIG. 8.

This effect, i.e. the effect that the slope in the voltage-time diagram for the induced voltage Ui is different from the slope in the voltage-time diagram for the pulsed voltage, and that this change is a function of the rotor position φ, may be utilized to unambiguously determine the rotor position φ, i.e. including the rotor polarity.

In the case of rectangular or PWM signals, the change in slope is relatively easy to determine, since in this case the slope of the pulsed voltage Up is zero (except for the transition between pulse and pause), so that it is only necessary to determine the slope of the induced voltage Ui. Of course, the slope itself does not have to be actually determined; it is sufficient to determine a measure of the slope.

In FIGS. 8 and 9 the slope is symbolized by dotted-line (slope) triangles. Due to interference signals not illustrated in FIGS. 8 and 9 but arising in practice upon pole reversal (see FIG. 5), it is recommended not to use measurement data recorded close to the pole reversal times for determining the slope.

A further advantage of the curve shape for the pulsed voltage Ui illustrated in FIG. 7 becomes clear at this point: the time period during which the slope is observable is much greater than for, for example, a 50/50 pulse as illustrated in FIG. 4, for example.

A measure of the slope may be easily obtained, for example, as the differential variable δU_{C} (in general: δUi), as shown in FIG. 8. In each case an average value is determined in the time periods designated by the horizontal arrows, for example by integration, and the difference in the voltages thus obtained is then determined as δU_{C}. Of course, this may be carried out multiple times to obtain more accurate values, for example at all the locations designated by a small circle in FIG. 9.

Of course, any other pulsed voltages may also be used; however, these generally require more complex evaluation than rectangular or PWM signals.

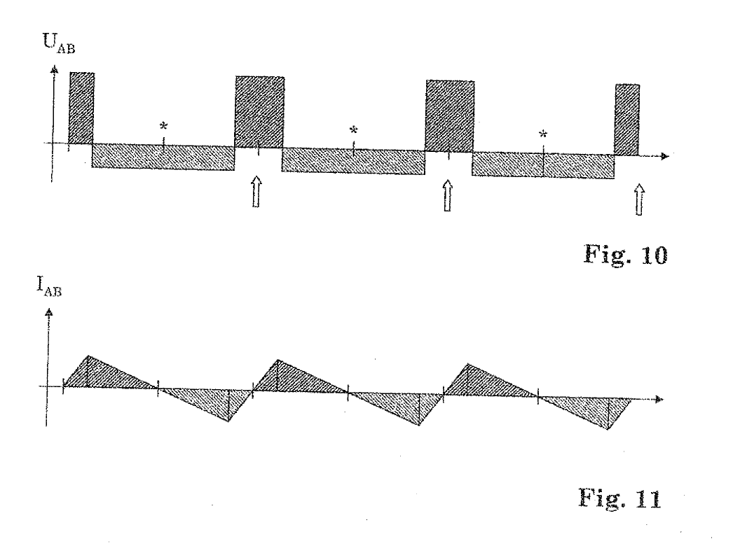

FIG. 10 schematically shows an example of an asymmetrically applied PWM signal U_{AB}.

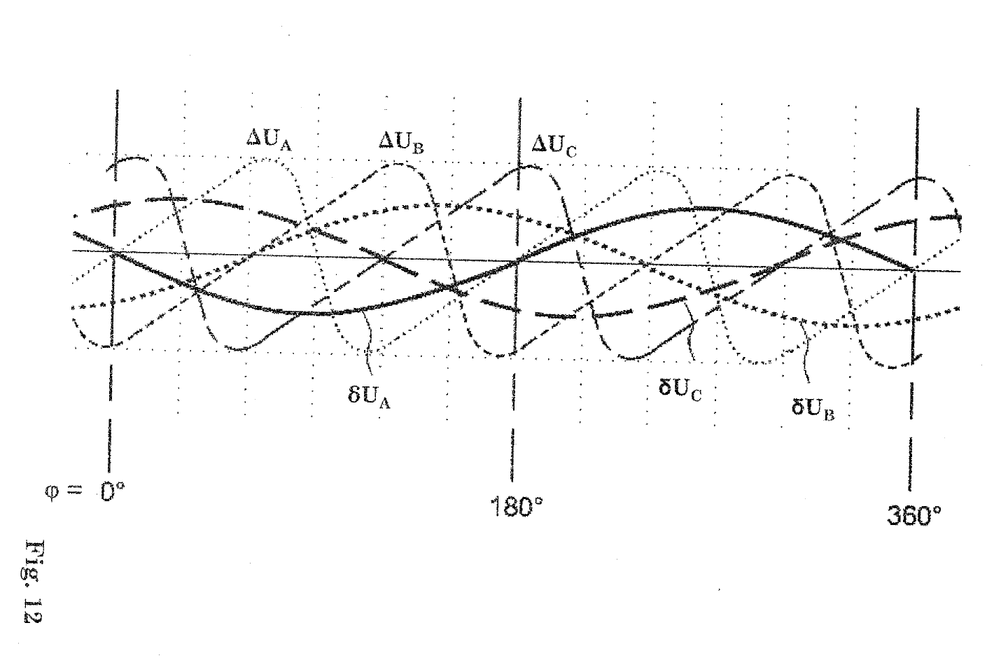

FIG. 11 shows the associated current-time diagram for I_{AB}.

The pulsed voltage U_{AB} (Up) advantageously ends at one of the locations identified by an outline arrow (or at a subsequent equivalent location, if the signal has a longer duration), since at that location the current is zero, and in addition the current-time integral vanishes. When the signal ends at one of the locations identified by “*”, at least the flowing current is zero. In principle, the pulsed voltage could be ended at any point in time, although this is generally accompanied by measurement inaccuracies, or results in longer measuring times. For illustration of the time integrals of U_{AB} or I_{AB}, in FIGS. 10 and 11 the corresponding areas are provided with a contrasting cross-hatched design, depending on the polarity sign.

The change in slope is analyzed, with reference to FIG. 1, using the analysis unit 34; i.e., δUi, for example, are determined at that location. The further evaluation loading from δUi to the rotor polarity is carried out in the evaluation unit 35.

FIG. 12 shows curves of δUi i.e., of δU_{A}, δU_{B}, δU_{C}, as a function of the rotor position φ. In practice, the curves do not necessarily show a shape as sinusoidal as illustrated in FIG. 12, but it is clear that the curves have a doubled period with respect to that of ΔU_{A}, ΔU_{B}, ΔU_{C}. Therefore, the rotor polarity may be determined by determining two or—which is better for reasons of measurement accuracy and redundancy—three δUi values.

Advantageously, δU_{A}, δU_{B}, δU_{C} and ΔU_{A}, ΔU_{B}, ΔU_{C} are determined (and in each case compared to one another) and compared to predetermined values (from measurements or models), thus allowing the rotor position to be unambiguously determined with great accuracy.

The comparative values are stored in the memory unit 17 (see FIG. 1).

Numerous variations are possible regarding the sequence of measurements, analyses, and evaluations.

For example, δU_{A}, δU_{B}, δU_{C} may be determined first, and then ΔU_{A}, ΔU_{B}, ΔU_{C}; or, δU_{A} and ΔU_{A} may be determined first, for example from the identical Up signal (for example, from the same or successive cycles of the pulsed voltage Up), and then δU_{B} and ΔU_{B}, and lastly δU_{C} and ΔU_{C}.

After the rotor position at standstill is unambiguously determined, the electrical machine may be run up in an optimal manner and then operated normally. For this purpose, the same components may be used as for the determination of the rotor position.

It is possible, using simple means, to unambiguously determine the rotor position with an accuracy of better than ±5°. This may be carried out very quickly due to the fact that frequencies of the pulsed voltage of ≧20 kHz and also ≧50 kHz (corresponding to cycle durations of ≦50 μs and ≦20 μs, respectively) may be readily used. Of course, lower frequencies may also be used.

It is noted that the described method and the device and system may be satisfactorily used without specific position sensors. Test signals (Up) are used, and the rotor position is determined based on the response of the system.

The pulsed voltage Up (U_{AB}, U_{BC}, U_{CA}) as test signal goes hand in hand with a varying current (I_{AB}; I_{BC}; I_{CA}), which causes a change in the magnetic flux. To keep the change in the current (I_{AB}; I_{BC}; I^{CA}) small, thus allowing, for example, overheating or damage to the machine to be prevented, the voltage Up is usually just a pulsed voltage generated by PWM which changes its polarity sign (pole reversal), so that the change in magnetic flux also periodically changes its polarity. This results in the respective free phase, in an approximate image of the pulsed voltage Up in the form of the induced voltage Ui (U_{A}, U_{B}, U_{C}). However, Ui is position-modulated, i.e. it varies as a function of the rotor position φ. Thus, the desired rotor position, even at a standstill, may be obtained by demodulation of this signal Ui.

Although the above explanations of the figures and method steps refer primarily to a motor, by analogy they may be easily transferred to generators.

Portions of the embodiments have been described by means of functional units. Of course, these may be implemented using any desired number of software and/or hardware components which are suitable for carrying out the cited functions. As an example, a battery may be used as the voltage source, and the switching or pole reversal for generating the pulsed voltage may be carried out using switch elements which may be regarded as being associated with the wiring system.

The invention makes it possible to unambiguously and unequivocally determine the rotor position of an electrical machine in a quick, accurate, cost-saving, and space-saving manner.

### LIST OF REFERENCE SYMBOLS

2 Input/output
3 Neutral point
17 Memory unit, memory device
30 Voltage source
31 Wiring system
32 Electrical machine
33 Voltage measuring device
34 Analysis unit
35 Evaluation unit
40 Arrangement
44 Appliance
A, B, C Phases
I Current
I_{AB}, I_{BC}, I_{CA} Current
N Magnetic north pole
S Magnetic south pole
U Voltage
Ui, U_{A}, U_{B}, U_{C} Induced voltage
Up, U_{AB}, U_{BC}, U_{CA} Pulsed voltage, pulsing voltage, pulsating voltage
ΔU_{A}, ΔU_{B}, ΔU_{C} Voltage difference
δU_{A}, δU_{B}, δU_{C} Measure, differential variable
φ Rotor position, rotor angle

1. Method for operating an electrical machine having a rotor and three phases and a connection associated with each of the phases, for determining the rotor position including the rotor polarity at a standstill, the method comprising for at least two of the phases the following steps are carried out:
a) applying a pulsed voltage between the two connections associated with the other two phases;
b) measuring the voltage thus induced at the connection associated with the phase;
c) analyzing the variation over time of said induced voltage;
and carrying out the following step:
d) determining the rotor polarity on the basis of said analyses.

2. Method according to claim 1, wherein in step c) a measure of the deviation of the variation over time of the induced voltage with respect to the variation over time of the pulsed voltage is determined.

3. Method according to claim 2, wherein the pulsed voltage has at least a portion showing a substantially constant voltage, and in step c) a measure of the slope of the induced voltage is determined during the at least one portion showing the substantially constant voltage.

4. Method according to claim 2, wherein the voltage-time integral of the pulsed voltage substantially vanishes.

5. Method according to claim 2, wherein the pulsed voltage is a rectangular or pulse width modulation signal.

6. Method according to claim 5, wherein the rectangular or pulse width modulation signal starts with a first state during a first time segment, followed by a second state, different from the first state, during a second time segment, the time integral of the pulsed voltage over the first and second time segments being substantially opposite and equal to the time integral of the pulsed voltage over the first time segment.

7. Method according to claim 6, the pulsed voltage ends with a third state during a third time segment, the time integral of the pulsed voltage over the third time segment being essentially equal to, or essentially opposite and equal to the time integral of the pulsed voltage over the first time segment.

8. Method according to claim 2 for determining the rotor position including the rotor polarity at a standstill, for the at least two phases the following step is carried out:
e) determining a voltage difference from said induced voltage;
and the following step is carried out:
f) determining the rotor position based on said voltage differences.

9. Method according to claim 2, wherein step d) comprises a comparison to predefined values.

10. Method according to claim 2, wherein the steps are carried out for all three phases.

11. Applicance for determining a rotor position including the rotor polarity at a standstill, of a rotor of an electrical machine having three phases and a connection associated with each of the phases, wherein the appliance comprises:
a voltage source for generating a pulsed voltage;
a voltage measuring device for measuring electrical voltages;
a wiring system for wiring the three connections selectably with the voltage source or the voltage measuring device;
wherein the appliance is designed in such a way that to at least two different pairs of the connections the pulsed voltage is successively applicable and an induced voltage thus occurring at the respective third connection is measurable using the voltage measuring device wherein the appliance further includes:
an analysis unit for analyzing the variation over time of the induced voltages measured using the voltage measuring device; and
an evaluation unit for determining the rotor polarity based on at least two of said analyses.

12. Appliance according to claim 11, wherein the voltage source is the voltage source which is provided also for normal operation of the electrical machine.

13. Appliance according to claim 12, wherein the analysis unit is provided for determining a measure the deviation of the variation over time of the induced voltage with respect to the variation over time of the pulsed voltage.

14. Appliance (44) according to claim 12, wherein the analysis unit is provided also for determining a voltage difference from said induced voltage, and the evaluation unit is provided also for determining the rotor position based on said voltage differences.

15. Appliance according to claim 14, further comprising a memory unit for storing comparative values for said voltage differences and/or comparative values for analysis results of said variations over time of said induced voltages.

16. Arrangement comprising an electrical machine having three phases and a connection associated with each of the phases and wherein the arrangement includes an appliance according to claim 11.

17. Method according to claim 1, wherein the pulsed voltage has at least a portion showing a substantially constant voltage, and in step c) a measure of the slope of the induced voltage is determined during the at least one portion showing the substantially constant voltage.

18. Method according to claim 1, wherein the voltage-time integral of the pulsed voltage substantially vanishes.

19. Method according to claim 1, wherein the pulsed voltage is a rectangular or pulse width modulation signal.

20. Method according to claim 1, for determining the rotor position including the rotor polarity at a standstill, for the at least two phases the following step is carried out:
e) determining a voltage difference from said induced voltage;
and the following step is carried out:
f) determining the rotor position based on said voltage differences.

21. Method according to claim 1, wherein step d) comprises a comparison to predefined values.

22. Method according to claim 1, wherein the steps are carried out for all three phases.

23. Appliance according to claim 11, wherein the analysis unit is provided for determining a measure of the deviation of the variation over time of the induced voltage with respect to the variation over time of the pulsed voltage.

24. Appliance according to claim 11, wherein the analysis unit is provided also for determining a voltage difference from said induced voltage, and the evaluation unit is provided also for determining the rotor position based on said voltage differences.
